(19) United States
(12) Patent Application Publication
(10) Pub. No.: US 2010/0133990 A1
(43) Pub. Date: Jun. 3, 2010

(54) ORGANIC LIGHT EMITTING DEVICE AND MANUFACTURING METHOD THEREOF

(76) Inventors: Sun PARK, Hwaseong-si (KR); Yul-Kyu LEE, Yongin-si (KR); Min-Hyuk CHOI, Cheongan-si (KR); Young-Dong KWON, Asan-si (KR)

Correspondence Address: F. CHAU & ASSOCIATES, LLC, 130 WOODBURY ROAD, WOODBURY, NY, 11797, US

(21) Appl. No.: 12/428,861

(22) Filed: Apr. 23, 2009

(30) Foreign Application Priority Data
Dec. 2, 2008 (KR) 10-2008-0121290

(51) Int. Cl. H01J 1/63; H01L 29/04; H01L 21/00

(52) U.S. Cl. 313/504; 257/59; 438/38; 257/E29.068; 257/E21.002

(57) ABSTRACT

An organic light emitting device includes a substrate including a display area and a peripheral area, a first signal line and a second signal line intersecting the first signal line, a switching thin film transistor electrically connected to the first signal line and the second signal line, a driving thin film transistor electrically connected to the switching thin film transistor, a pixel electrode electrically connected to the driving thin film transistor, a light emitting member disposed on the pixel electrode, a common electrode disposed on the light emitting member, a blocking member disposed on at least one of the first signal line and the second signal line in the peripheral area, the blocking member comprising protruding and recessed portions, and a sealant disposed on the blocking member, the sealant overlapping a portion of the blocking member.

### CROSS REFERENCE TO RELATED APPLICATION

This application claims priority to Korean Patent Application No. 10-2008-0121290 filed on Dec. 2, 2008, the entire contents of which are incorporated herein by reference.

### BACKGROUND OF THE INVENTION

(a) Technical Field

The present disclosure relates to an organic light emitting device and a manufacturing method thereof, and more particularly to an organic light emitting device having a blocking member including protruding and recessed portions and a manufacturing method thereof.

(b) Discussion of Related Art

An organic light emitting device includes two electrodes and an organic light emitting layer interposed between the two electrodes. One of the two electrodes injects holes and the other electrode injects electrons into the organic light emitting layer. The injected electrons and holes are combined to form excitons. The excitons emit light when the energy state of the excitons is dropped from an excited state to a ground state.

The organic light emitting device is a self-emission type of display that does not require a light source. However, in the organic light emitting device, corrosion of metal wirings may occur due to moisture or etchants coming in contact with the metal wirings during manufacturing.

### SUMMARY OF THE INVENTION

In an organic light emitting device according to an exemplary embodiment of the present invention, a blocking member including protruding and recessed portions overlaps a sealant of a peripheral area such that corrosion of wiring may be prevented and adhesion of a lower panel and an upper panel may improve.

According to an exemplary embodiment, an organic light emitting device includes a substrate including a display area and a peripheral area, a first signal line and a second signal line intersecting each other, a switching thin film transistor electrically connected to the first signal line and the second signal line, a driving thin film transistor electrically connected to the switching thin film transistor, a pixel electrode electrically connected to the driving thin film transistor, a light emitting member formed on the pixel electrode, a common electrode formed on the light emitting member, a blocking member formed on at least one of the first signal line and the second signal line in the peripheral area and including protrusions and depressions, and a sealant formed on the blocking member and overlapping a portion of the blocking member.

A passivation layer formed on the first signal line and the second signal line may be further included, and the passivation layer and the blocking member may comprise the same material.

At least a portion of the outer boundary of the sealant may be covered by the blocking member.

The blocking member may be formed on at least one edge of the display area.

The protrusions and depressions may be formed with a stripe shape.

The blocking member may include an opening passing through the blocking member, and the opening is formed with a stripe shape.

The first signal line and the second signal line may be made in a plurality, the blocking member may include an opening disposed at between the first signal lines, between the second signal lines, or both, and the opening may include a plurality of holes.

The blocking member may cover at least one of the first signal lines and the second signal lines, and may overlap the sealant with an island shape.

According to an exemplary embodiment of the present invention, a method of manufacturing an organic light emitting device includes forming a switching thin film transistor and a driving thin film transistor connected to the switching thin film transistor on a substrate including a display area and a peripheral area, simultaneously forming a blocking member including protrusions and depressions in the peripheral area while forming the passivation layer in the display area on the switching thin film transistor and the driving thin film transistor, forming a pixel electrode connected to the driving thin film transistor on the passivation layer, forming a light emitting member on the pixel electrode, forming a common electrode on the light emitting member, and forming a sealant overlapping a portion of the blocking member on the blocking member.

The passivation layer and the blocking member may be made of the same material.

The blocking member may be formed by using a half-tone mask.

According to an exemplary embodiment of the present invention, the blocking member including protrusions and depressions overlaps the sealant of the peripheral area such that anti-corrosion of wiring may improve and adhesion of a lower panel and an upper panel may improve.

### BRIEF DESCRIPTION OF THE DRAWINGS

Exemplary embodiments of the present invention can be understood in more detail from the following descriptions taken in conjunction with the accompanying drawings, in which:

FIG. 1 is a circuit diagram of an organic light emitting device according to an exemplary embodiment of the present invention;

FIG. 2 is a layout view of an A region of the organic light emitting device shown in FIG. 1 according to an exemplary embodiment of the present invention;

FIG. 3 is a cross-sectional view of the organic light emitting device shown in FIG. 2 taken along the line III-III according to an exemplary embodiment of the present invention;

FIG. 4 is a layout view of a B region of the organic light emitting device shown in FIG. 1 according to an exemplary embodiment of the present invention;

FIG. 5 is a cross-sectional view of the organic light emitting device shown in FIG. 4 taken along the line V-V according to an exemplary embodiment of the present invention;

FIG. 6 is a layout view of a portion of a peripheral area in an organic light emitting device according to an exemplary embodiment of the present invention;

FIG. 7 is a cross-sectional view of the organic light emitting device shown in FIG. 6 taken along the line VII-VII according to an exemplary embodiment of the present invention;

FIG. 8 is a layout view of a portion of a peripheral area in an organic light emitting device according to an exemplary embodiment of the present invention;

FIG. 9 is a cross-sectional view of the organic light emitting device shown in FIG. 8 taken along the line IX-IX according to an exemplary embodiment of the present invention; and

FIG. 10 is a flowchart of a method of forming an organic light emitting device according to an exemplary embodiment of the present invention.

### DETAILED DESCRIPTION OF EXEMPLARY EMBODIMENTS

The present invention will be described more fully hereinafter with reference to the accompanying drawings, in which exemplary embodiments of the invention are shown. This invention may, however, be embodied in many different forms and should not be construed as limited to the exemplary embodiments set forth herein.

It will be understood that when an element such as a layer, film, region, or substrate is referred to as being “on” another element, it can be directly on the other element or intervening elements may also be present.

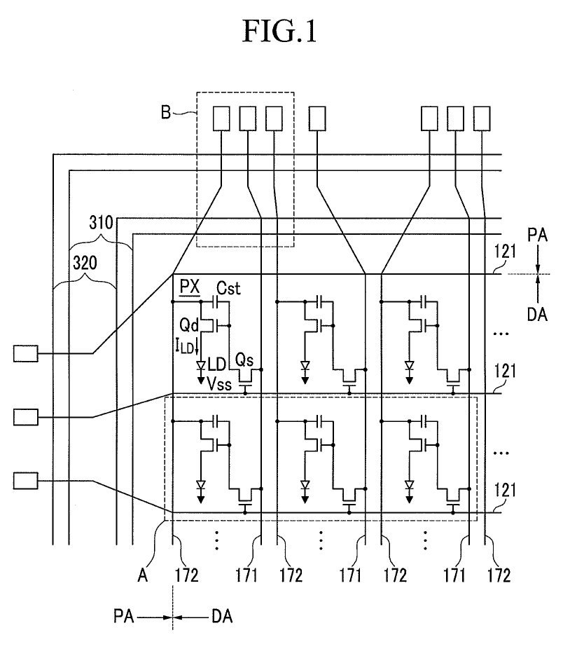

FIG. 1 is a circuit diagram of an organic light emitting device according to an exemplary embodiment of the present invention.

Referring to FIG. 1, an organic light emitting device includes a plurality of signal lines 121, 171, and 172, and a plurality of pixels PX connected thereto and arranged substantially in matrix. A plurality of the pixels PX form a display area DA, and the outer area of the pixels PX form a peripheral area PA. A blocking member 320 enclosing the pixels PX and a sealant 310 are formed in the peripheral area PA. The blocking member 320 and the sealant 310 overlap partially.

The signal lines include a plurality of gate signal lines 121 for transmitting gate signals or scanning signals, a plurality of data lines 171 for transmitting data signals, and a plurality of driving voltage lines 172 for transmitting a driving voltage. The gate signal lines 121 extend substantially in a row direction and are substantially parallel to each other, and the data lines 171 extend substantially in a column direction and are substantially parallel to each other.

Each pixel PX includes a switching transistor Qs, a driving transistor Qd, a storage capacitor Cst, and an organic light emitting element LD.

The switching transistor Qs includes a control terminal, an input terminal, and an output terminal. The control terminal is connected to the scanning signal line 121, the input terminal is connected to the data line 171, and the output terminal is connected to the driving transistor Qd. The switching transistor Qs transmits the data signal received from the data line 171 to the driving transistor Qd in response to the scanning signal received from the scanning signal line 121.

The driving transistor Qd includes a control terminal, an input terminal, and an output terminal. The control terminal is connected to the switching transistor Qs, the input terminal is connected to the driving voltage line 172, and the output terminal is connected to the organic light emitting element LD. The driving transistor Qd applies an output current ILD to the organic light emitting element LD. The magnitude of the output current ILD varies according to the voltage applied between the control terminal and the output terminal.

The capacitor Cst is connected between the control terminal and the input terminal of the driving transistor Qd. The capacitor Cst stores the data signal applied to the control terminal of the driving transistor Qd and maintains the stored data signal even after the switching transistor Qs is turned off.

In an exemplary embodiment, the organic light emitting element LD can be an organic light emitting diode (OLED) having an anode connected to the output terminal of the driving transistor Qd and a cathode connected to a common voltage Vss. The organic light emitting element LD emits light. The intensity of the light is varied according to the output current ILD of the driving transistor Qd, to display an image.

In an exemplary embodiment, the switching transistor Qs and the driving transistor Qd are n-channel field effect transistors (FET). In an exemplary embodiment, at least one of the switching transistor Qs and the driving transistor Qd may be a p-channel FET. In an exemplary embodiment, the connection relationship among the transistors Qs and Qd, the storage capacitor Cst, and the organic light emitting element LD may be changed.

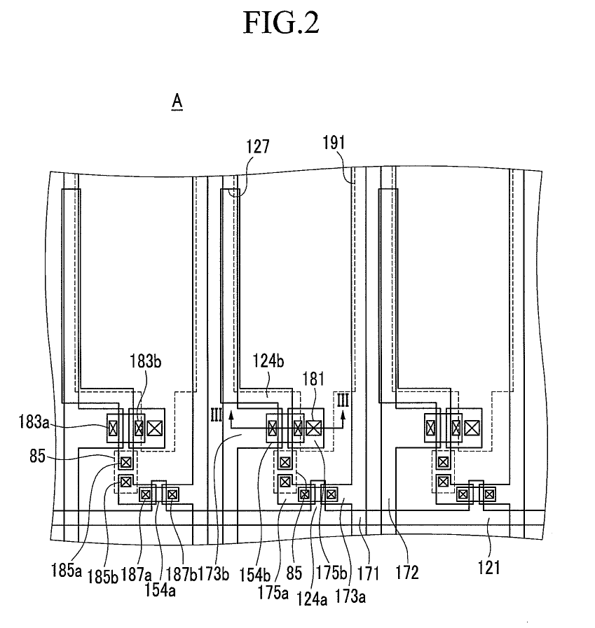

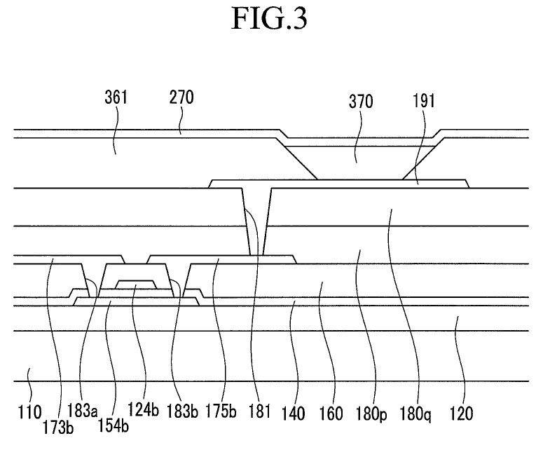

FIG. 2 is a layout view of an A region of the organic light emitting device shown in FIG. 1 according to an exemplary embodiment of the present invention. FIG. 3 is a cross-sectional view of the organic light emitting device shown in FIG. 2 taken along the line III-III according to an exemplary embodiment of the present invention.

Referring to FIG. 2 and FIG. 3, a first interlayer insulating layer 120 comprising, for example, silicon nitride (SiNx) or silicon oxide (SiOx) is formed on a first substrate 110 comprising, for example, transparent glass or plastic. The first interlayer insulating layer 120 has a function of a buffer separating a driving semiconductor 154b and the first substrate 110.

The driving semiconductor 154b is formed on the first interlayer insulating layer 120. The driving semiconductor 154b can have an island shape, and may comprise a semiconductor material such as, for example, microcrystalline silicon or polycrystalline silicon.

The driving semiconductor 154b includes a doping region and a non-doping region. The doping regions are disposed on both sides of the non-doping region, and comprise crystalline silicon doped with an n-type impurity such as phosphorous (P) or a p-type impurity such as boron (B). The non-doping region may comprise an intrinsic semiconductor that is not doped with an impurity, and forms a channel of the driving thin film transistor.

A gate insulating layer 140 comprising, for example, silicon nitride (SiNx) or silicon oxide (SiOx) is formed on the driving semiconductor 154b.

Each of the gate lines 121 including a switching control electrode 124a and a driving control electrode 124b are formed on the gate insulating layer 140. The gate lines 121 extend in one direction of the substrate. The gate lines 121 include the switching control electrode 124a extending upwardly, and an end portion for a connection with an external driving circuit. The driving control electrode 124b is separated from the gate line 121, and includes a storage electrode 127 extending upwardly.

The gate line 121 and the driving control electrode 124b may comprise a refractory metal such as, for example, a molybdenum-containing metal including molybdenum (Mo) or a molybdenum alloy, a chromium-containing metal including chromium (Cr) or a chromium alloy, a titanium-containing metal including titanium (Ti) or a titanium alloy, a tantalum-containing metal including tantalum (Ta) or a tantalum alloy, and a tungsten-containing metal including tungsten (W) or a tungsten alloy, or a low resistance metal such as, for example, aluminum (Al), copper (Cu), or silver (Ag).

A second interlayer insulating layer 160 comprising, for example, silicon nitride (SiNx) or silicon oxide (SiOx) is formed on the gate line 121 and the driving control electrode 124b.

Driving voltage lines 172 including a driving input electrode 173b and a driving output electrode 175b are formed on the second interlayer insulating layer 160.

The driving voltage lines 172 substantially extend in a longitudinal direction, thereby intersecting the gate lines 121, and transmit a driving voltage. The driving voltage lines 172 include the driving input electrode 173b on the driving semiconductors 154b. A portion of the driving voltage lines 172 overlaps the storage electrodes 127 of the driving control electrodes 124b to form a storage capacitor (Cst).

The driving output electrodes 175b are separated from the driving voltage lines 172 and have, for example, an island shape. The driving input electrodes 173b and the driving output electrodes 175b are respectively electrically connected to the doping regions of the driving semiconductor 154b through contact holes 183a and 183b. The driving voltage lines 172 and the driving output electrodes 175b may comprise the refractory metal, or a low resistance metal such as, for example, aluminum (Al), copper (Cu), or silver(Ag), as a single layer or as a multilayered structure. In an exemplary embodiment, the multilayered structure can be molybdenum (Mo)/aluminum (Al)/molybdenum (Mo) layers.

The description of a switching semiconductor 154a, the switching control electrode 124a, and the data line 171 including a switching input electrode 173a and a switching output electrode 175a forming the switching thin film transistor, contact holes 187a and 187b may be equally or similarly applied with the description of the above-described driving thin film transistor.

A first passivation layer 180p and a second passivation layer 180q are formed on the driving voltage line 172, the driving output electrode 175b, and the switching output electrode 175a. The first passivation layer 180p and the second passivation layer 180q may comprise an inorganic insulating material or an organic material having a good planarization characteristic, such as, for example, a polyacryl. One of the first passivation layer 180p and the second passivation layer 180q may be omitted according to an exemplary embodiment of the present invention.

A pixel electrode 191 and a connecting member 85 are formed on the second passivation layer 180q, and the pixel electrode 191 is electrically connected to the driving output electrode 175b through a contact hole 181. The pixel electrode 191 and the connecting member 85 may comprise a transparent conductor such as, for example, ITO or IZO. The connecting member 85 electrically connects the switching output electrode 175a and the driving control electrode 124b through the contact holes 185a and 185b.

A pixel definition layer 361 comprising, for example, an organic insulating material is formed on the pixel electrode 191. The pixel definition layer 361 encloses the edge of the pixel electrode 191 like, for example, a bank. Accordingly, the pixel definition layer 361 includes an opening formed in each pixel.

A light emitting member 370 is formed on the pixel electrode 191. The light emitting member 370 fills the opening of the pixel definition layer 361.

The light emitting member 370 may comprise a multi-layered structure including light emission layers and an auxiliary layer for improving light emitting efficiency.

The light emission layers may be formed by vertically or horizontally forming respective emission layer of red, green, and blue in one pixel to emit white light. The respective emission layer may comprise a high molecular weight material, a low molecular weight material, or a mixture thereof to emit light of one of the primary colors including red, green, and blue.

The auxiliary layer may include at least one selected from an electron transport layer and a hole transport layer for balancing electrons and holes, and an electron injection layer and a hole injection layer for reinforcing the injection of the electrons and the holes.

A common electrode 270 is formed on the light emitting member 370 and the pixel definition layer 361. The common electrode 270 can be formed on the whole surface of the first substrate 110, and may comprise an opaque conductor such as, for example, Au, Pt, Ni, Cu, W, or an alloy thereof.

The common electrode 270 supplies current to the light emitting members 370 in cooperation with the pixel electrodes 191. A pixel electrode 191, a light emitting member 370, and the common electrode 270 form an organic light emitting diode LD having the pixel electrode 191 as an anode and the common electrode 270 as a cathode, or vice versa.

In exemplary embodiments, the interlayer structure or the arrangement structure of the switching thin film transistor and the driving thin film transistor may have various shapes. That is, in an organic light emitting device according to an exemplary embodiment of the present invention, when the driving semiconductor 154b comprises polysilicon, the gate electrode 124b corresponding to the driving semiconductor 154b can be disposed on the driving semiconductor 154b. In an exemplary embodiment, when the driving semiconductor 154b comprises amorphous silicon, the gate electrode can be disposed under the semiconductor layer 154b. In an exemplary embodiment, one of the semiconductors 154a and 154b included in the driving thin film transistor and switching thin film transistor may comprise the polysilicon, and the other may comprise the amorphous silicon.

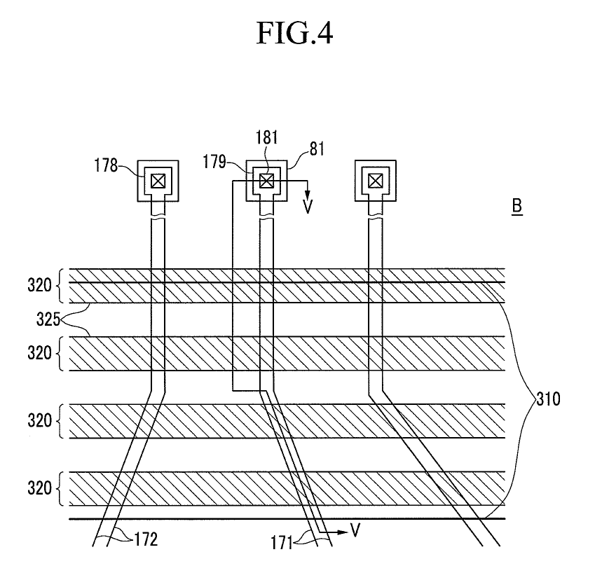

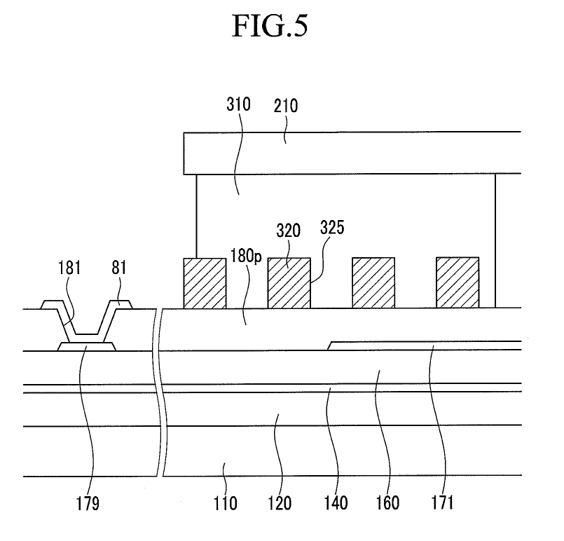

FIG. 4 is a layout view of the B region of the organic light emitting device shown in FIG. 1 according to an exemplary embodiment of the present invention. FIG. 5 is a cross-sectional view of the organic light emitting device shown in FIG. 4 taken along the line V-V according to an exemplary embodiment of the present invention.

Referring to FIG. 4 and FIG. 5, the first interlayer insulating layer 120, the gate insulating layer 140, and the second interlayer insulating layer 160 are sequentially formed on the first substrate 110. The data line 171, an end portion 179 of the data line 171, the driving voltage line 172, and an end portion 178 of the driving voltage line 171 are formed on the second interlayer insulating layer 160. The first passivation layer 180p is formed on the data line 171, on the end portion 179 of the data line 171, on the driving voltage line 172, and on the end portion 178 of the driving voltage line 172. The first passivation layer 180p has the contact hole 181 exposing the end portion 179 of the data line 171 or the end portion 178 of the driving voltage line 172. A connecting member 81, and the end portion 179 of the data line 171 or the end portion 178 of the driving voltage line 172, are electrically connected to each other through the contact hole 181. In an exemplary embodiment, the connecting member 81 may be simultaneously formed with the pixel electrode 191 using a same material.

The blocking member 320 comprising, for example, an organic material is formed on the first passivation layer 180p. The blocking member 320 may be simultaneously formed with the second passivation layer 180q using a same material. The blocking member 320 is formed in the peripheral area PA, and the blocking member 320 may be disposed on at least one of the upper, lower, right, or left portions of the peripheral area PA. The blocking member 320 covers at least one of a portion of the gate line 121, a portion of the data line 171, and a portion of the driving voltage line 172. Accordingly, the blocking member 320 may prevent the gate line 121, the data line 171, and the driving voltage line 172 from being corroded by an etchant used for an etch process.

The blocking member 320 includes an opening 325 exposing a portion of the first passivation layer 180p. The opening 325 is substantially parallel to the gate line 121. In an exemplary embodiment, the shape and number of openings may be variously changed. The blocking member 320 including the opening 325 has a linear shape or a curved shape having various protruding and recessed portions. The protruding and recessed portions improve a cohesion intensity of the first substrate 110 including the thin film transistor and a second substrate 210. The protruding and recessed portions may be formed in one of the row direction and the column direction, or in both directions. The protruding and recessed portions can be formed in an irregular shape.

The sealant 310 is formed on the blocking member 320. The outer boundary of the blocking member 320 is disposed farther from the display area DA than the outer boundary of the sealant 310. The inner boundary of the blocking member 320 may be disposed farther from the display area DA than the inner boundary of the sealant 310. Accordingly, the blocking member 320 may prevent moisture or the etchant from penetrating into the outer boundary of the sealant 310, thereby preventing the corrosion of the signal lines such as the data line 171, the driving voltage line 172, and the gate line 121.

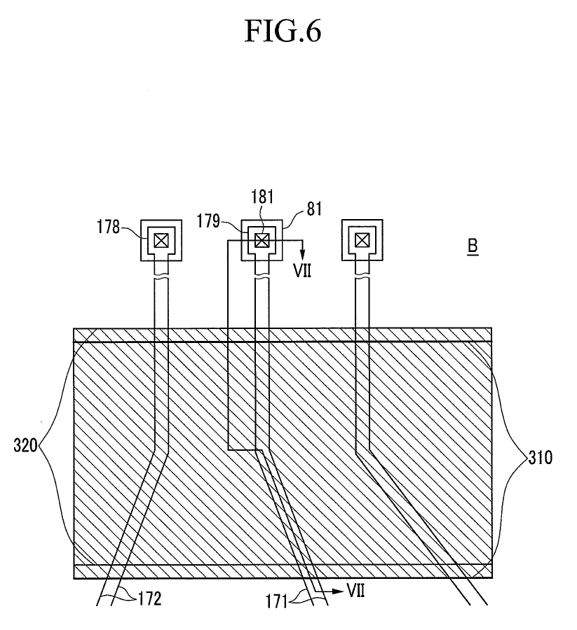

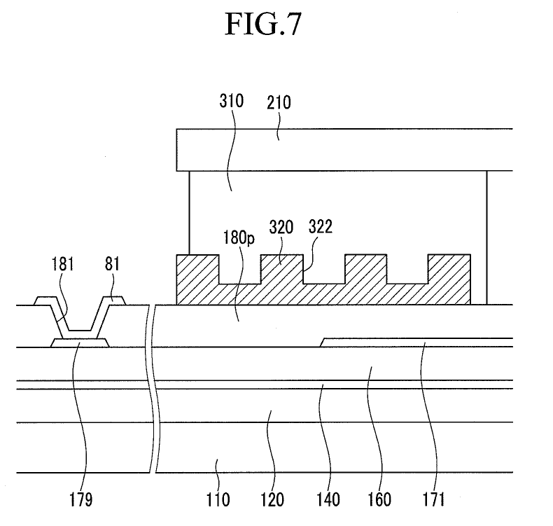

An organic light emitting device according to an exemplary embodiment of the present invention is described with reference to FIG. 6 and FIG. 7.

FIG. 6 is a layout view of a portion of a peripheral area in an organic light emitting device according to an exemplary embodiment of the present invention. FIG. 7 is a cross-sectional view of the organic light emitting device shown in FIG. 6 taken along the line VII-VII according to an exemplary embodiment of the present invention.

Referring to FIGS. 1, 6 and 7, in the peripheral area PA of the organic light emitting device, the blocking member 320 includes a recessed portion 322. In an exemplary embodiment, the area occupied with the blocking member 320 is wide under the sealant 310 such that the anti-corrosion of the metal signal lines such as the data line 171, the driving voltage line 172, and the gate line 121 may improve. Since the blocking member 320 has the linear and curved shape including the protruding and recessed portions such as the recess portion 322, the adhesion intensity between the first substrate 110 and the second substrate 210 may improve. In an exemplary embodiment, the first passivation layer 180p is omitted.

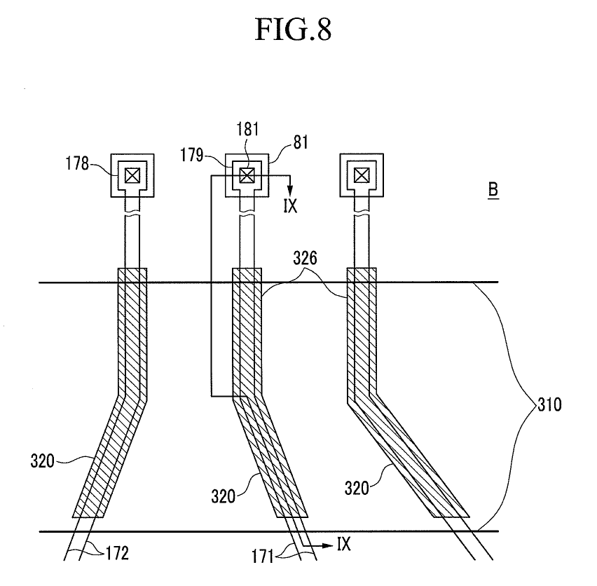

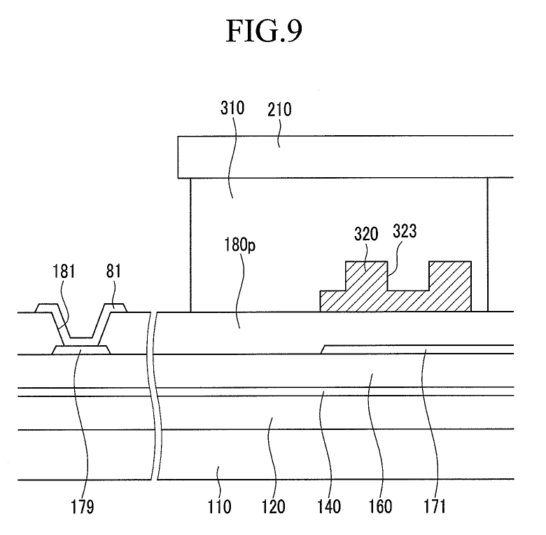

An organic light emitting device according to an exemplary embodiment of the present invention is described with reference to FIG. 8 and FIG. 9.

FIG. 8 is a layout view of a portion of a peripheral area in an organic light emitting device according to an exemplary embodiment of the present invention. FIG. 9 is a cross-sectional view of the organic light emitting device shown in FIG. 8 taken along the line IX-IX according to an exemplary embodiment of the present invention.

Referring to FIGS. 1, 8 and 9, in the peripheral area PA of the organic light emitting device, a hole 326 passing through the blocking member 320 is formed between the data line 171 and the driving voltage line 172.

In an exemplary embodiment, the blocking member 320 is formed on the whole surface of the data line 171 and the driving voltage line 172 to prevent the corrosion of the metal signal lines such as the data line 171, the driving voltage line 172, and the gate line 121. When the blocking member 320 is formed on the whole surface of the data line 171 and the driving voltage line 172, the contact area of the blocking member 320 and the sealant 310 may further increase. Accordingly, the adhesion intensity of the first substrate 110 and the second substrate 210 may improve. In an exemplary embodiment, a hole passing through the blocking member 320 may have a smaller area than the hole 326 shown in FIG. 8, and the shape and volume of the hole may be variously changed. For example, the hole can have a cylinder shape. In an exemplary embodiment, the blocking member 320 covering the data line 171 and the driving voltage line 172 may include a recessed portion 323, and an opening cutting the blocking member 320 in the horizontal direction. For example, the opening can be similar to the opening 325 described in connection with FIG. 5.

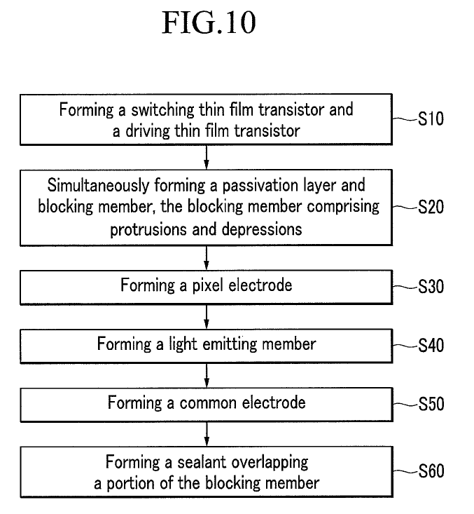

FIG. 10 is a flowchart showing a method of forming an organic light emitting device according to an exemplary embodiment of the present invention.

A switching thin film transistor and a driving thin film transistor connected to the switching thin film transistor are formed on a first substrate 110 (S10). The thin film transistors and the electrode may be formed using a thin film deposition process and a patterning process such as photolithography. In an exemplary embodiment, the gate insulating layer 140, the first interlayer insulating layer 120, and the second interlayer insulating layer 160 may be deposited between elements of the thin film transistors.

The first passivation layer 180p is formed on the switching thin film transistor and the driving thin film transistor.

The second passivation layer 180q and a blocking member 320 are simultaneously formed on the first passivation layer 180p with the same material (S20). In an exemplary embodiment, in forming the blocking member 320, the opening may be formed with various shapes and numbers by using, for example, a half-tone mask including slits, lattices, or a semi-transparent film, and the recessed portion 322 may be formed with various shapes and numbers. In an exemplary embodiment, the recessed portion 322 may be formed with an embossing pattern including a curved surface.

The connecting member 81 connected to the end portion 129 of the gate line 121 and the pixel electrode 191 connected to the driving thin film transistor are simultaneously formed on the second passivation layer 180q with the same material (S30). The connecting member 81 and the pixel electrode 191 can be formed using, for example, a deposition process and a patterning process.

The pixel definition layer 361 enclosing the pixel electrode 191 is formed on the pixel electrode 191. In an exemplary embodiment, the opening of the pixel definition layer 361 is formed through the photolithography process.

The light emitting member 370 is formed on the pixel electrode 191 (S40). The light emitting member 370 is formed inside a bank of the pixel definition layer 361.

The common electrode 270 is formed on the light emitting member 370 (S50). The common electrode 270 may be deposited on the whole surface of the first substrate 110.

The sealant 310 overlapping a portion of the blocking member 320 is formed on the blocking member 320 (S60).

Then, the first substrate 110 and the second substrate 210 are combined.

Although the exemplary embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. An organic light emitting device comprising:
a substrate including a display area and a peripheral area;
a first signal line and a second signal line intersecting the first signal line;
a switching thin film transistor electrically connected to the first signal line and the second signal line;
a driving thin film transistor electrically connected to the switching thin film transistor;
a pixel electrode electrically connected to the driving thin film transistor;
a light emitting member disposed on the pixel electrode;
a common electrode disposed on the light emitting member;
a blocking member disposed on at least one of the first signal line or the second signal line in the peripheral area, the blocking member comprising protruding and recessed portions; and
a sealant disposed on the blocking member, the sealant overlapping a portion of the blocking member.

2. The organic light emitting device of claim 1, further comprising
a passivation layer disposed on the first signal line and the second signal line,
wherein the passivation layer and the blocking member comprise the same material.

3. The organic light emitting device of claim 1, wherein
the blocking member covers at least a portion of an outer boundary of the sealant.

4. The organic light emitting device of claim 3, wherein
the blocking member is disposed on at least one side of the display area.

5. The organic light emitting device of claim 4, wherein
the protruding and recessed portions are disposed with a stripe shape.

6. The organic light emitting device of claim 1, wherein
the blocking member includes an opening passing through the blocking member.

7. The organic light emitting device of claim 6, wherein
the opening is disposed with a stripe shape.

8. The organic light emitting device of claim 7, wherein
the blocking member covers at least a portion of an outer boundary of the sealant.

9. The organic light emitting device of claim 8, wherein
the blocking member is disposed on at least one side of the display area.

10. The organic light emitting device of claim 9, wherein
the protruding and recessed portions are disposed in at least one direction.

11. The organic light emitting device of claim 6, wherein
the first signal line and the second signal line are formed in a plurality, and
the blocking member includes an opening disposed at between the first signal lines, between the second signal lines, or between the first and second signal lines.

12. The organic light emitting device of claim 11, wherein
the opening includes a plurality of holes.

13. The organic light emitting device of claim 11, wherein
the blocking member covers at least one of the first signal lines and the second signal lines, the blocking member overlapping the sealant with an island shape.

14. The organic light emitting device of claim 11, wherein
the blocking member covers at least a portion of an outer boundary of the sealant.

15. The organic light emitting device of claim 14, wherein
the blocking member is disposed on at least one side of the display area.

16. The organic light emitting device of claim 15, wherein
the protruding and recessed portions are extended in at least one direction.

17. The organic light emitting device of claim 1, wherein
the protruding and recessed portions are extended in at least one direction.

18. The organic light emitting device of claim 1, wherein
the protruding and recessed portions have a stripe shape or a curved line shape.

19. A method for manufacturing an organic light emitting device, comprising:
forming a switching thin film transistor and a driving thin film transistor on a substrate including a display area and a peripheral area, the driving thin film transistor connected to the switching thin film transistor;
forming a blocking member including protruding and recessed portions in the peripheral area;
forming a passivation layer on the switching thin film transistor and the driving thin film transistor in the display area;
forming a pixel electrode connected to the driving thin film transistor on the passivation layer;
forming a light emitting member on the pixel electrode;
forming a common electrode on the light emitting member; and
forming a sealant overlapping a portion of the blocking member on the blocking member.

20. The method of claim 19, wherein forming a blocking member including protruding and recessed portions in the peripheral area and forming a passivation layer on the switching thin film transistor and the driving thin film transistor in the display area are performed simultaneously.
